(19) United States
(12) Patent Application Publication
(10) Pub. No.: US 2026/0104769 A1
(43) Pub. Date: Apr. 16, 2026

(54) DISPLAY PANEL AND DISPLAY APPARATUS

(71) Applicant: Yungu (Gu’an) Technology Co., Ltd., Langfang (CN)

(72) Inventors: Junhui LOU, Langfang (CN); Haijing SHEN, Langfang (CN); Haifeng LU, Langfang (CN); Rubo XING, Langfang (CN)

(73) Assignee: Yungu (Gu’an) Technology Co., Ltd., Langfang (CN)

(21) Appl. No.: 19/417,268

(22) Filed: Dec. 11, 2025

Related U.S. Application Data
(63) Continuation of application No. PCT/CN2023/136308, filed on Dec. 5, 2023.

(30) Foreign Application Priority Data
Jun. 30, 2023 (CN) 202310796409.8

(51) Int. Cl. G06F 3/041; G06F 3/044; H10K 59/122; H10K 59/40

(52) U.S. Cl. CPC G06F 3/0412; G06F 3/044; H10K 59/122; H10K 59/40

(57) ABSTRACT

Embodiments of the present application provide a display panel and a display apparatus. The display panel includes: a substrate; an isolation structure, the isolation structure including isolation portions, and a light-emitting unit being provided within a corresponding one of the isolation openings; and a functional layer including first electrodes and touch electrodes, a corresponding one of the first electrodes being arranged within a corresponding one of the isolation openings and located on a side of the light-emitting unit away from the substrate, the touch electrodes being located on a side of the isolation portions away from the substrate, and the first electrodes being insulated and spaced apart from the touch electrodes. In the present application, by arranging the isolation structure, the functional layer can be separated into the first electrodes and the touch electrodes, simplifying the structure of the display panel without separately providing a touch structure layer.

### CROSS-REFERENCE TO RELATED APPLICATIONS

The present application is a continuation of International Application No. PCT/CN2023/136308 filed on December 05, 2023, which claims priority to Chinese Patent Application No. 202310796409.8, entitled "DISPLAY PANEL AND DISPLAY APPARATUS" and filed on June 30, 2023, which is incorporated herein by reference in its entirety.

### FIELD

The present application relates to the field of display devices, and particularly to a display panel and a display apparatus.

### BACKGROUND

An organic light-emitting diode (OLED) is an active light-emitting device. Compared with a conventional liquid crystal display (LCD) method, OLED display technology does not require a backlight and has self-luminous properties. The OLED uses a thin film layer of an organic material and a glass substrate. When a current passes through the film layer of the organic material, the organic material emits light. Therefore, OLED display panels can significantly save energy and be made lighter and thinner, tolerate a wider range of temperature changes than LCD display panels, and have a larger viewing angle. The OLED display panel technology is expected to become the next generation of flat panel display technology after LCD technology, and is one of the flat panel display technologies that have attracted most attention currently.

Existing OLED display devices include a touch module, which is usually of an add-on type. The add-on touch patch is attached to a surface of a display screen body, which leads to increased structural complexity and thickness of the display devices.

### SUMMARY

Embodiments of the present application provide a display panel and a display apparatus, with a view to simplifying the structure of the display panel.

An embodiment of a first aspect of the present application provides a display panel. The display panel includes: a substrate; an isolation structure arranged on the substrate, the isolation structure including isolation portions and isolation openings enclosed by the isolation portions, and a light-emitting unit being provided within a corresponding one of the isolation openings; and a functional layer including first electrodes and touch electrodes, a corresponding one of the first electrodes being arranged within a corresponding one of the isolation openings and located on a side of the light-emitting unit away from the substrate, the touch electrodes being located on a side of the isolation portions away from the substrate, and the first electrodes being insulated and spaced apart from the touch electrodes.

An embodiment of a second aspect of the present application further provides a display apparatus, including a display panel according to any one of the above embodiments of the first aspect.

In the display panel according to this embodiment of the present application, the display panel includes a substrate, an isolation structure, and a functional layer. The isolation structure includes isolation portions and isolation openings, and a light-emitting unit is provided within a corresponding one of the isolation openings to implement the luminous display of the display panel. The functional layer includes first electrodes and touch electrodes, where a corresponding one of the first electrodes is located within a corresponding one of the isolation openings and arranged on the light-emitting unit to drive the light-emitting unit to emit light. The touch electrodes are arranged on a side of the isolation portions away from the substrate, and the isolation structure can isolate the touch electrodes from the first electrodes, and the first electrodes and the touch electrodes are less prone to short-circuit connection. Therefore, in the present application, by arranging the isolation structure, the functional layer can be separated into the first electrodes and the touch electrodes, simplifying the structure of the display panel without separately providing a touch structure layer.

### BRIEF DESCRIPTION OF THE DRAWINGS

FIG. 1 is a top view of a display panel according to an embodiment of the present application;

FIG. 2 is a cross-sectional view along line A-A in FIG. 1;

FIG. 3 is a structural schematic partial enlarged view of FIG. 1 according to one example;

FIG. 4 is a structural schematic partial enlarged view of FIG. 1 according to another example;

FIG. 5 is a structural schematic partial enlarged view of FIG. 1 according to still another example;

FIG. 6 is a structural schematic partial enlarged view of FIG. 1 according to yet another example;

FIG. 7 is a structural schematic partial enlarged view of FIG. 1 according to still yet another example;

FIG. 8 is a structural schematic partial enlarged view of FIG. 1 according to still yet another example;

FIG. 9 is a top view of a display panel according to another embodiment of the present application;

FIG. 10 is a top view of a display panel according to still another embodiment of the present application;

FIG. 11 is a partial cross-sectional view of a display panel according to an embodiment of the present application;

FIG. 12 is a partial cross-sectional view of a display panel according to another embodiment of the present application;

FIG. 13 is a partial cross-sectional view of a display panel according to still another embodiment of the present application;

FIG. 14 is a partial cross-sectional view of a display panel according to yet another embodiment of the present application;

FIG. 15 is a partial cross-sectional view of a display panel according to still yet another embodiment of the present application;

FIG. 16 is a partial cross-sectional view of a display panel according to yet another embodiment of the present application; and

FIG. 17 is a partial cross-sectional view of a display panel according to still yet another embodiment of the present application.

### DETAILED DESCRIPTION OF THE EMBODIMENTS

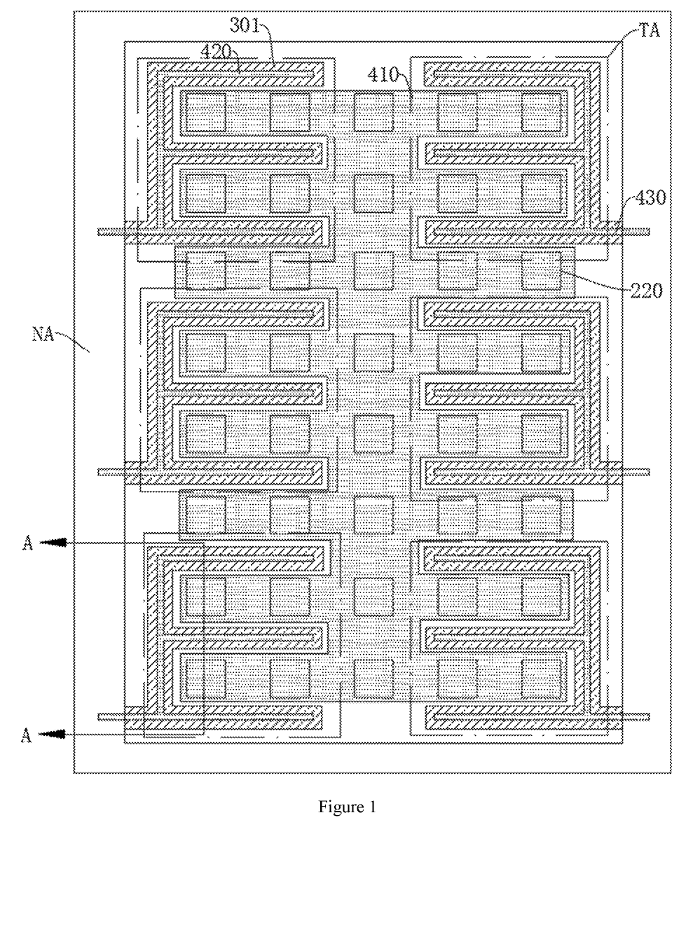

In order to better understand the present application, a display panel and a display apparatus according to the embodiments of the present application will be described in detail below with reference to FIGS. 1 to 17.

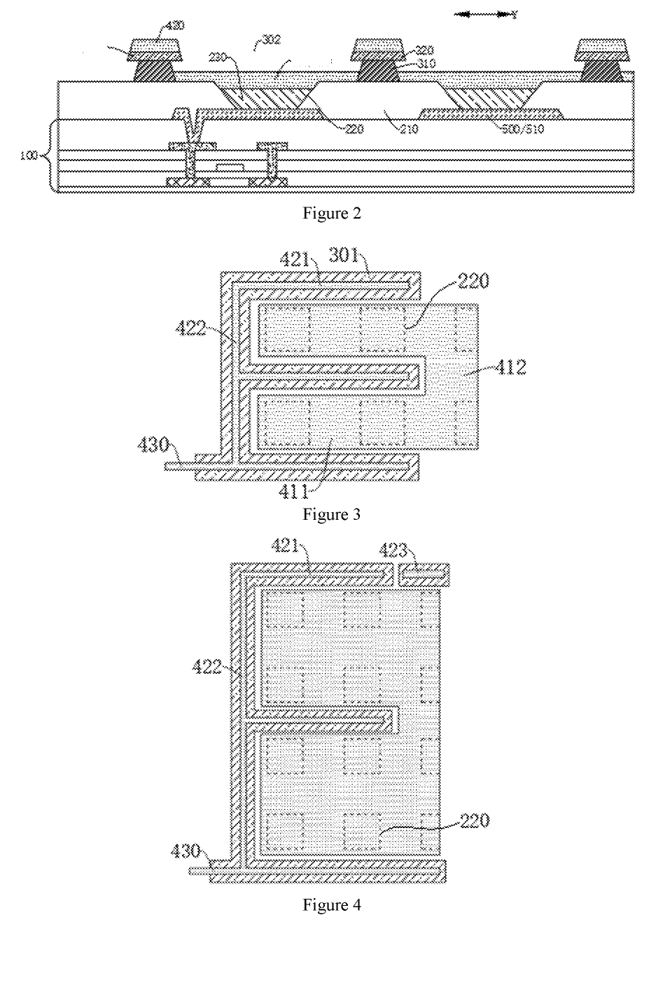

Referring to FIGS. 1 to 2 together, FIG. 1 is a top view of a display panel according to an embodiment of the present application. FIG. 2 is a cross-sectional view along line A-A in FIG. 1.

As shown in FIGS. 1 and 2, an embodiment of a first aspect of the present application provides a display panel. The display panel includes a substrate 100, an isolation structure 300, and a functional layer 400. The isolation structure 300 is arranged on the substrate 100, the isolation structure 300 including isolation portions 301 and isolation openings 302 enclosed by the isolation portions 301, and a light-emitting unit 230 being provided within a corresponding one of the isolation openings 302. The functional layer 400 includes first electrodes 410 and touch electrodes 420, a corresponding one of the first electrodes 410 being arranged within a corresponding one of the isolation openings 302 and located on a side of the light-emitting unit 230 away from the substrate 100, the touch electrodes 420 being located on a side of the isolation portions 301 away from the substrate 100, and the first electrodes 410 being insulated and spaced apart from the touch electrodes 420.

In the display panel according to this embodiment of the present application, the display panel includes the substrate 100, the isolation structure 300, and the functional layer 400. The isolation structure 300 includes the isolation portions 301 and the isolation openings 302, and the light-emitting unit 230 is provided within a corresponding one of the isolation openings 302 to implement the luminous display of the display panel. The functional layer 400 includes the first electrodes 410 and the touch electrodes 420, where a corresponding one of the first electrodes 410 is located within a corresponding one of the isolation openings 302 to drive the light-emitting unit 230 to emit light. The touch electrodes 420 are arranged on a side of the isolation portions 301 away from the substrate 100, and the isolation structure 300 can isolate the touch electrodes 420 from the first electrodes 410, and the first electrodes 410 and the touch electrodes 420 are less prone to short-circuit connection. Therefore, in the present application, by arranging the isolation structure 300, the functional layer 400 can be separated into the first electrodes 410 and the touch electrodes 420, simplifying the structure of the display panel without separately providing a touch structure layer.

In one embodiment, at least part of the touch electrodes 420 are provided with gaps, and correspondingly, at least part of isolation portions 301 used to support the touch electrodes 420 are provided with gaps, and at least part of the first electrodes 410 are located in the gaps and are electrically connected to each other through the gaps.

In this embodiment of the present application, the isolation structure 300 is added and the functional layer 400 can be divided into the first electrodes 410 and the touch electrodes 420, and in addition, it can be ensured that the first electrodes 410 can be interconnected into a continuous electrode by providing gaps between the isolation portions 301. On the basis of simplifying the structure of the display panel, the problem that the same layer arrangement of the touch electrodes 420 and the first electrodes 410 affects the interconnection of the first electrodes 410 into the continuous electrode is also solved.

In one embodiment, the display panel includes an active area AA. The continuous electrode here is not an electrode that is physically laid out over the entire surface, meaning that the continuous electrode is not an electrode that is laid out over the entire active area AA, but is obtained by interconnecting all the first electrodes 410 within the active area AA, and the first electrodes 410 within the active area AA have a same potential. In one embodiment, the display panel further include a non-active area NA arranged around the active area AA.

In one embodiment, the display panel further includes a pixel define layer 200. The pixel define layer 200 is arranged on the substrate 100. The pixel define layer 200 includes a pixel defining portion 210 and pixel openings 220 enclosed by the pixel defining portion 210. A corresponding one of the pixel openings 220 is located within a corresponding one of the isolation openings 302. The light-emitting unit 230 is located within a corresponding one of the pixel openings 220.

In one embodiment, the display panel further includes a second electrode layer 500, and the second electrode layer 500 includes second electrodes 510. A corresponding one of the second electrodes 510 is located on a side of the light-emitting unit 230 facing the substrate and cooperates with a corresponding one of the first electrodes 410 to drive the light-emitting unit 230 to emit light.

In one embodiment, the substrate 100 may include a substrate base and an array substrate. The array substrate may include a drive circuit. For example, the array substrate may include a first signal line layer, a second signal line layer, and a third signal line layer that are arranged on a side of the substrate base and that are stacked. An insulation layer is provided between adjacent signal line layers. For example, a pixel driving circuit arranged on the array substrate includes a transistor and a storage capacitor. The transistor includes a semiconductor, a gate, a source, and a drain. The storage capacitor includes a first plate and a second plate. As an example, the gate and the first plate may be located in the first signal line layer, the second plate may be located in the second signal line layer, and the source and the drain may be located in the third signal line layer.

In one embodiment, during the preparation of the display panel, a functional material layer may be deposited on the isolation structure 300. A part falling within an isolation opening 302 of the isolation structure 300 forms a first electrode 410, and a part falling on an isolation portion 301 of the isolation structure 300 forms a touch electrode 420, and the first electrode 410 and the touch electrode 420 can be prepared and formed in the same process step, thereby simplifying the preparation process of the display panel.

Referring to FIGS. 1 to 3 together, FIG. 3 is a structural schematic partial enlarged view of FIG. 1. To more clearly illustrate the structure of the display panel, locations where the pixel openings 220 are arranged are shown in FIG. 3 with dashed lines.

The touch electrode 420 may be shaped in a variety of ways. In some embodiments, as shown in FIGS. 1 to 3, the touch electrode 420 includes first touch portions 421 and a second touch portion 422. There are two or more first touch portions 421. The first touch portions 421 extend in a first direction X. The two or more first touch portions 421 are connected by the second touch portion 422.

In these embodiments, the touch electrode 420 is comb-shaped by being configured as first touch portions 421 and a second touch portion 422. This can increase a distribution area of the touch electrode 420, and can also enable the first electrodes 410 to be interconnected into a continuous electrode through gaps between adjacent first touch portions 421.

In one embodiment, the second touch portion 422 extends in a second direction Y and connects adjacent first touch portions 421.

In one embodiment, the gap in "at least part of the touch electrodes 420 are provided with gaps" above may be: a gap between two first touch portions 421 within a same touch electrode 420, and/or a gap between two adjacent touch electrodes 420. The gap between the two adjacent touch electrodes 420 may be: a gap between second touch portions 422 of the two adjacent touch electrodes 420, and/or a gap between a second touch portion 422 of one of the two adjacent touch electrodes 420 and a first touch portion 421 of the other; and/or a gap between two first touch portions 421 of the two adjacent touch electrodes 420.

In some embodiments, as shown in FIG. 4, at least two of the first touch portions 421 have different lengths. The touch electrodes 420 may further include a dummy electrode 423. The dummy electrode 423 is arranged on a side of a shorter first touch portion 421, and the dummy electrode 423 is insulated from the first touch portion 421, the second touch portion 422, and the first electrodes 410. By adding the dummy electrode 423, areas of touch electrodes 420 distributed throughout the display panel may be more even, thereby improving the uniformity of the display panel.

In one embodiment, the dummy electrode 423 is arranged on a side of the shorter first touch portion 421 in the first direction X, and a sum of dimensions of the dummy electrode 423 and the shorter first touch portion 421 in the first direction is close to a length of a longer first touch portion 421, thereby better mitigating the problem of display non-uniformity on the display panel.

In one embodiment, shapes of the isolation structure 300 and the touch electrodes 420 are adapted to each other, i.e., the isolation structure 300 exists to support the touch electrodes 420. In one embodiment, the isolation portions 301 include a first isolation portion and a second isolation portion, an orthographic projection of a corresponding one of the first touch portions 421 on the substrate 100 is within an orthographic projection of the first isolation portion on the substrate 100, and an orthographic projection of the second touch portion 422 on the substrate 100 is within an orthographic projection of the second isolation portion on the substrate 100.

In these embodiments, the first isolation portion is arranged corresponding to the first touch portion 421, and the second isolation portion is arranged corresponding to the second touch portion 422. By providing the first isolation portion, the first touch portion 421 and the first electrode 410 can be insulated from each other, and by providing the second isolation portion, the second touch portion 422 and the second electrode can be insulated from each other. Locations of the first isolation portion and the second isolation portion are not indicated in FIG. 3. The first isolation portion is arranged in the same location as the first touch portion 421, and the second isolation portion is arranged in the same location as the second touch portion 422.

In one embodiment, gaps are formed between adjacent first isolation portions, and the first electrodes 410 are interconnected into a continuous electrode through the adjacent first isolation portions.

In some embodiments, each of the first electrodes 410 includes first electrode portions 411 and a second electrode portion 412, a corresponding one of the first electrode portions 411 being located between two adjacent ones of the first touch portions 421, a plurality of first electrode portions 411 being spaced apart in the second direction Y, and the second electrode portion 412 connecting two adjacent ones of the first electrode portions 411.

In these embodiments, the touch electrode 420 is substantially comb-shaped by being configured as first touch portions 421 and a second touch portion 422, and the first electrode 410 is substantially comb-shaped by being configured as first electrode portions 411 and a second electrode portion 412. A corresponding one of the first electrode portions 411 is located between adjacent first touch portions 421, enabling the first electrode 410 and the touch electrode 420 to interdigitate with each other. This enables both the touch electrode 420 and the first electrode 410 to be arranged at different locations in the active area AA, and can also ensure that the touch electrode 420 and the first electrode 410 are insulated from each other.

In one embodiment, at least part of the second electrode portion 412 and the second touch electrode portion 422 are respectively arranged on two sides of a same first touch electrode portion 421. For example, the second touch electrode portion 422 connected to a specific first touch electrode portion 421, and the second electrode portion 412 connecting first electrode portions 411 located on two sides of the first touch electrode portion 421 are respectively arranged on the two sides of the first touch electrode portion 421 in the first direction X, and the arrangement of the second electrode portion 412 and the second touch electrode portion 422 does not affect each other.

For example, still referring to FIGS. 1 to 3, the display panel includes a plurality of touch areas TA. Each touch electrode 420 is located in area corresponding one touch area TA. That is, the same touch electrode 420 is provided in each touch area TA. In the same touch area TA, the second electrode portion 412 and the second touch portion 422 are respectively arranged on two sides, of the first electrode portion 411 and the first touch portion 421, in the first direction X.

In these embodiments, the display panel includes the plurality of touch areas TA, where each touch area TA is provided with a touch electrode 420 to implement the touch function of the display panel. A first electrode portion 411 is provided between adjacent first touch portions 421 of the touch electrode 420, that is, a touch area TA is provided with both a touch electrode 420 and a first electrode 410. In the same touch area TA, the second electrode portion 412 and the second touch portion 422 are respectively arranged on the two sides, of the first electrode portion 411 and the first touch portion 421, in the first direction X, and the second touch portion 422 may not affect the connection of the second electrode portion 412 to adjacent first electrode portions 411, ensuring that the first electrode portion 411 and the second electrode portion 412 are interconnected into a continuous electrode.

In one embodiment, at least one row of pixel openings 220 is correspondingly provided between two adjacent first touch portions 421, and the first direction X is a row direction. This enables the first electrode 410 located between the two adjacent first touch portions 421 to drive light-emitting units 230 within the at least one row of pixel openings 220 to emit light.

In one embodiment, as shown in FIG. 4, one or more pixel openings 220 arranged in the second direction Y are provided between two adjacent ones of the first touch portions 421. That is, two or more rows of pixel openings 220 are provided between two adjacent first touch portions 421, and first electrodes 410 corresponding to two adjacent rows of pixel openings 220 can be directly electrically connected to each other, thereby reducing an overall resistance of the first electrodes 410.

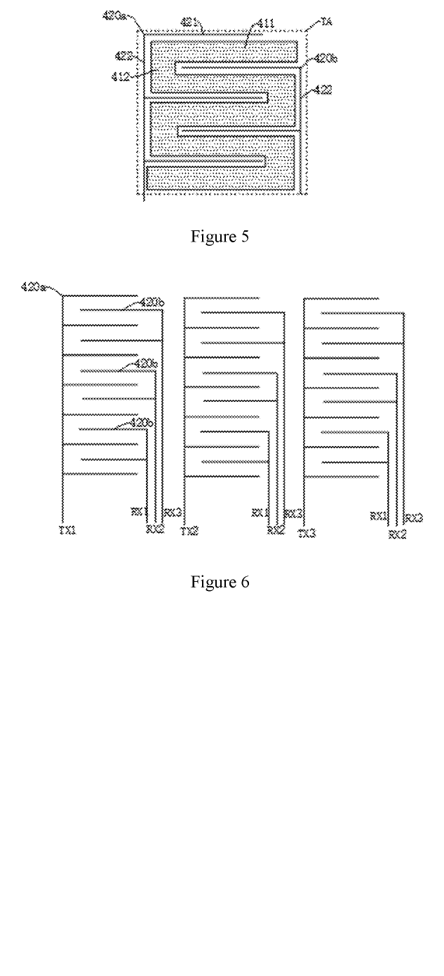

In some other embodiments, as shown in FIG. 5, when the touch area TA is provided with two touch electrodes 420, and first touch portions 421 of the two touch electrodes 420 are alternately distributed in the second direction Y, and second touch portions 422 of the two touch electrodes 420 are respectively arranged on two sides of the first touch portions 421 in the first direction X, the first electrode portion 411 may be S-shaped and first electrodes 410 can be electrically connected to each other through gaps between the two touch electrodes 420 that are interdigitated with each other.

In one embodiment, a gap is provided between adjacent touch electrodes 420, and the first electrode portion 411 and/or the second electrode portion 412 located in different touch areas TA can be electrically connected to each other through the gap to form a continuous electrode.

The touch electrode 420 may be configured in a variety of ways. The touch electrode 420 may be a self-capacitive touch electrode or a mutual-capacitive touch electrode. For example, each of the touch electrodes 420 is a mutual-capacitive touch electrode. The touch electrode 420 includes a first touch electrode 420a and a second touch electrode 420b. The first touch electrode 420a and the second touch electrode 420b each include first touch portions 421 and a second touch portion 422.

In one embodiment, as shown in FIGS. 6 and 7, when the touch electrode 420 is a mutual-capacitive touch electrode 420, at least among a first touch electrode 420a and a second touch electrode 420b that are adjacent, a first touch portion 421 of the first touch electrode 420a and a first touch portion 421 of the second touch electrode 420b are alternately distributed in a second direction Y.

In these embodiments, by enabling the first touch portion 421 of the first touch electrode 420a and the first touch portion 421 of the second touch electrode 420b to be alternately distributed in the second direction Y, both the first touch electrode 420a and the second touch electrode 420b may be arranged at different locations in the active area AA, enabling both the first touch electrode 420a and the second touch electrode 420b to be relatively evenly distributed at different locations in the active area AA.

In one embodiment, a first electrode portion 411 is provided between the first touch portion 421 of the first touch electrode 420a and the first touch portion 421 of the second touch electrode 420b that are adjacent. In one embodiment, at least part of the second electrode portion 412 is located on a side of the first touch portion 421 of the first touch electrode 420a away from the second touch portion 422, or at least part of the second electrode portion 412 is located on a side of the first touch portion 421 of the second touch electrode 420b away from the second touch portion 422, to connect the first electrode portion 411 between the first touch portion 421 of the first touch electrode 420a and the first touch portion 421 of the second touch electrode 420b that are adjacent.

In one embodiment, as shown in FIG. 5, the first electrode 410 is S-shaped. For example, a plurality of first electrode portions 411 are spaced apart in the second direction Y. Second electrode portions 412 adjacent in the second direction Y are separately arranged on two sides of the first electrode portion 411 in the first direction X and connect adjacent first electrode portions 411.

In one embodiment, first touch electrodes 420a and second touch electrodes 420b are distributed in an array in the first direction X and the second direction Y. One or more first touch electrodes 420a may be arranged in the second direction Y. One or more second touch electrodes 420b may be arranged corresponding to a same first touch electrode 420a. That is, the first touch portion 421 of the same first touch electrode 420a and first touch portions 421 of the one or more second touch electrodes 420b may be alternately distributed in the second direction Y.

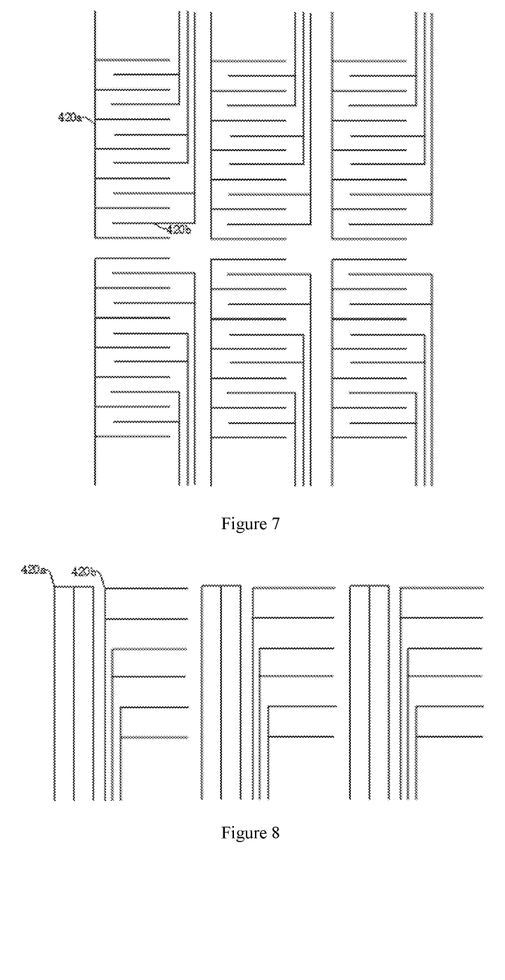

In some other embodiments, as shown in FIG. 8, a plurality of second touch electrodes 420b arranged side by side in a second direction Y are provided between two first touch electrodes 420a adjacent in the first direction X. In these embodiments, the first touch electrode 420a and the second touch electrode 420b are arranged side by side rather than intersect with each other, which can mitigate a problem that the first touch electrode 420a and the second touch electrode 420b are prone to short-circuit connection.

In the above embodiments, In one embodiment, an extension direction of the first touch portion 421 of the first touch electrode 420a and an extension direction of the second touch portion 422 of the second touch electrode 420b may be the same or different. The first direction X is an extension direction of a first touch portion 421 within a same touch electrode 420, and the second direction Y is a side-by-side arrangement direction of a plurality of first touch portions 421 within a same touch electrode 420. The first direction X and the second direction Y of different touch electrodes 420 may be in a same direction or in opposite directions.

In some embodiments, as shown in FIG. 1, the display panel includes a plurality of touch areas TA, the plurality of touch areas TA being distributed in an array in the first direction X and the second direction Y, and two adjacent touch areas TA are equidistant in the first direction X and/or the second direction Y. The distribution of the plurality of touch areas TA is made more even, and the display effect of the display panel is more even.

In one embodiment, one touch electrode or two or more touch electrodes 420 may be provided in a same touch area TA. For example, one first touch electrode 420a or one second touch electrode 420b may be provided in a same touch area TA. In one embodiment, a group of first touch electrodes 420a and second touch electrodes 420b may be provided in a same touch area TA, and the first touch portion 421 of the first touch electrode 420a and the first touch portion 421 of the second touch electrode 420b are alternately distributed in the second direction Y, that is, the first touch electrode 420a and the second touch electrode 420b are provided in the same touch area TA and are interdigitated with each other.

In one embodiment, a number of touch electrodes 420 provided in each touch area TA is the same, and the touch electrodes 420 are more evenly distributed in the plurality of touch areas TA, achieving a more even display effect of the display panel.

In some embodiments, as shown in FIGS. 1, 9, and 10, the touch electrode 420 is located in the active area AA of the display panel, and the touch electrode 420 is a self-capacitive touch electrode 420. The functional layer 400 further includes touch leads 430 connected to touch electrodes 420. The touch leads 430 are located on a side of the isolation portions 301 away from the substrate 100. The plurality of touch leads 430 extend to at least two sides of the active area AA of the display panel.

In these embodiments, the functional layer 400 further includes the touch leads 430 connected to the touch electrodes 420, and the touch electrodes 420 can transmit touch signals through the touch leads 430. The plurality of touch leads 430 extend to the at least two sides of the active area AA of the display panel, and the plurality of touch leads 430 can be relatively evenly distributed on the display panel, which can improve the display effect of the display panel.

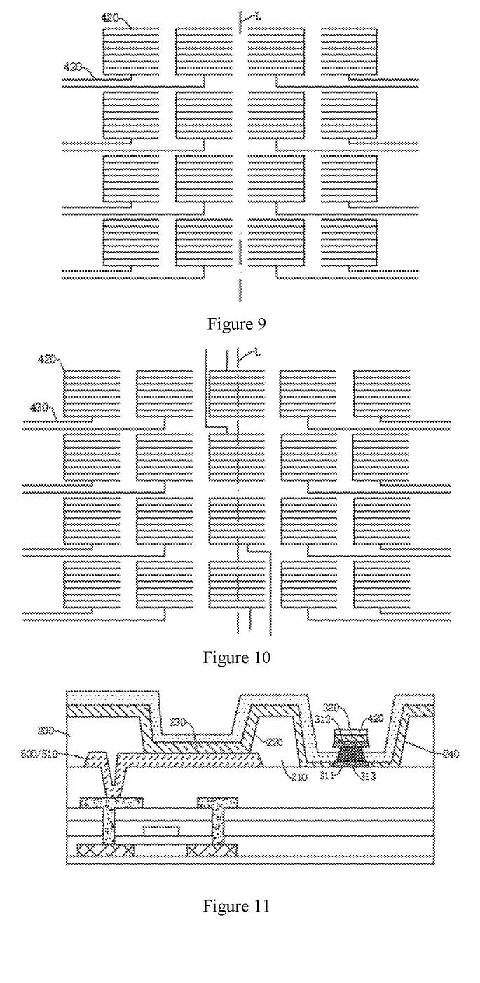

In one embodiment, FIGS. 9 and 10 only show locations of the touch electrodes 420 and touch leads 430 in the functional layer 400. The first electrodes 410 may be set at locations other than the locations of the touch electrodes 420 and the touch leads 430.

In one embodiment, the plurality of touch electrodes 420 are arranged in an array in a first direction X and a second direction Y, the active area AA of the display panel and the plurality of touch electrodes 420 are symmetrically arranged about a first reference line L in the second direction Y, and the touch leads 430 connected to the touch electrodes 420 located on two sides of the first reference line L extend in a direction away from the first reference line L. This enables the touch electrodes 420 and touch leads 430 more evenly, and also makes extension distances of the touch leads 430 smaller, which improves the display effect while ensuring the transmission of touch signals.

In one embodiment, as shown in FIG. 9, when an even number of touch electrodes 420 are provided in a same row, the first direction X is a row direction, and the even number of touch electrodes 420 are separately arranged on two sides of the first reference line L.

In one embodiment, as shown in FIG. 10, when an odd number of touch electrodes 420 are provided in a same row, at least one column of touch electrodes 420 is symmetrically arranged about the first reference line L, that is, the first reference line L overlaps with the plurality of touch electrodes 420 arranged in the second direction Y. Then, touch leads 430 connected to the touch electrodes 420 that overlap with the first reference line L extend to two sides of the active area AA in the second direction Y, making the wiring of the touch leads 430 more even and further improving the display effect of the display panel.

In one embodiment, as shown in FIGS. 9 and 10, when a plurality of touch leads 430 are led out from a same side of the display panel, there may be at least part of the plurality of touch leads 430 that are arranged side by side. As shown in FIG. 9, there are two touch leads 430 arranged side by side on the outside of the plurality of touch electrodes 420. In one embodiment, at least part of a corresponding one of the first electrodes 410 is located between two adjacent touch leads 430 that are at least partially arranged side by side. In other words, the first electrodes 410 may be provided between adjacent touch leads 430 arranged side by side to increase the distribution area of the first electrodes 410, and the first electrodes 410 can be interconnected into a continuous electrode.

In one embodiment, the isolation structure 300 may be arranged at a variety of locations on the substrate 100. For example, as shown in FIG. 2, the isolation structure 300 may be arranged on a side of the pixel defining portion 210 away from the substrate 100. During the preparation of the display panel, after the pixel define layer 200 is prepared and formed, the isolation structure 300 can be further prepared on the pixel defining portion 210. The preparation method of the isolation structure 300 is simple and convenient.

In some other embodiments, as shown in FIG. 11, the isolation structure 300 may be directly arranged on a surface of the substrate 100. For example, the pixel define layer 200 is further provided with hollow openings 240. The hollow openings 240 are enclosed by the pixel defining portion 210, and at least part of the substrate 100 is exposed from a corresponding one of the hollow openings 240, and the isolation structure 300 may be directly arranged on the substrate 100 exposed from the hollow opening 240. In one embodiment, the isolation structure 300 and an inner wall surface of the pixel defining portion 210 facing the hollow opening 240 are spaced apart. This makes it difficult for the functional layer 400 to be continuous between the isolation structure 300 and the pixel defining portion 210, and the first electrode 410 and the touch electrode 420 are less prone to short-circuit connection.

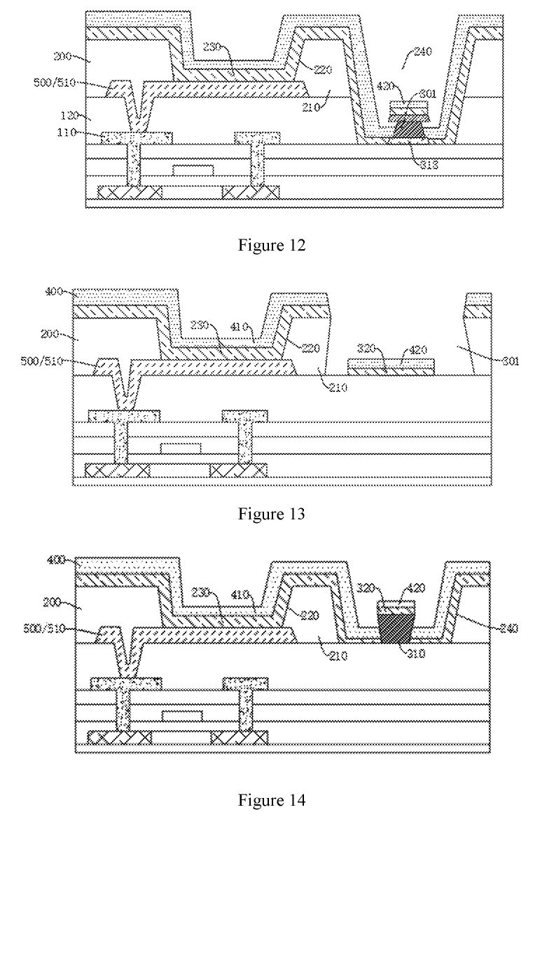

In still other embodiments, as shown in FIG. 12, the substrate 100 includes a metal layer 110 and an insulating dielectric layer 120 located between the metal layer 110 and the pixel define layer 200. The pixel defining portion 210 further encloses the hollow openings 240. The insulating dielectric layer 120 is provided with a clearance opening that is in communication with a corresponding one of the hollow openings 240. The isolation structure 300 is located in the clearance opening and the hollow opening 240. The metal layer 110 and at least part of the conductive portion 310 are made of a same material, to simplify the preparation process of the display panel. The metal layer 110 may be at least one of the first signal line layer, the second signal line layer, and the third signal line layer described above, or the metal layer 110 may be a separate signal line layer. The insulating dielectric layer 120 may be a planarization layer, a gate insulating dielectric layer, or the like.

In still other embodiments, as shown in FIG. 13, each of the isolation portions 301 is formed by a recess in a surface of the pixel defining portion 210 away from the substrate 100. That is, the isolation portion 301 is a partition groove. The partition groove enables a segment gap to be formed between an upper surface of the pixel defining portion 210 away from the substrate 100 and a bottom surface of the partition groove, and the first electrode 410 and the touch electrode 420 are disconnected from each other at an edge of the partition groove during the preparation of the functional layer 400. In one embodiment, a cross-sectional dimension of the isolation portion 301 gradually increase in a direction approaching the substrate 100; and in the direction approaching the substrate 100, the cross-sectional dimension of the partition groove gradually increases, and a recess may be formed on an inner wall surface of the partition groove, enabling the first electrode 410 and the touch electrode 420 to be more likely to be disconnected at the edge of the partition groove.

In one embodiment, the partition groove (that is, the isolation portion 301) runs through the pixel define layer 200 to increase a depth of the partition groove, enabling the first electrode 410 and the touch electrode 420 to be more likely to be disconnected at the edge of the partition groove.

In one embodiment, the partition groove (that is, the isolation portion 301) may further extend from the pixel define layer 200 into the interior of the substrate 100. For example, the substrate 100 further includes a planarization layer, and the partition groove runs through the pixel defining portion 210 and at least part of the planarization layer to further increase the depth of the partition groove, enabling the first electrode 410 and the touch electrode 420 to be more likely to be disconnected at the edge of the partition groove.

In some embodiments, the isolation structure 300 includes a conductive portion 310 and an insulation portion 320 located on a side of the conductive portion 310 away from the substrate 100, the touch electrode 420 is located on a side of the insulation portion 320 away from the substrate 100, and the first electrode 410 and the conductive portion 310 are electrically connected to each other.

In these embodiments, the first electrode 410 and the conductive portion 310 are electrically connected to each other, and the first electrodes 410 can be interconnected by the conductive portion 310 into a continuous electrode, and the impedance of the first electrode 410 can be reduced.

The insulation portion 320 is provided in a variety of materials, for example, the insulation portion 320 may include an organic insulation layer and/or an inorganic insulation layer, i.e., the material of the insulation portion 320 may include an organic insulating material and/or an inorganic insulating material.

In one embodiment, an orthographic projection of the conductive portion 310 on the substrate 100 is within an orthographic projection of the insulation portion 320 on the substrate 100, i.e., a size of the conductive portion 310 is less than or equal to a size of the insulation portion 320, and a segment gap can be formed between the conductive portion 310 and the insulation portion 320, or one side of the conductive portion 310 can form a recess, and the functional layer 400 can break at the edge of the isolation structure 300 to form the first electrode 410 and the touch electrode 420.

In one embodiment, as shown in FIGS. 2 and 11, the conductive portion 310 includes a first sub-layer 311 and a second sub-layer 312 located on a side of the first sub-layer 311 away from the substrate 100, the first sub-layer 311 and the first electrode 410 being electrically connected to each other, an orthographic projection of the first sub-layer 311 on the substrate 100 being within an orthographic projection of the second sub-layer 312 on the substrate 100, and the orthographic projection of the second sub-layer 312 on the substrate 100 being within an orthographic projection of the insulation portion 320 on the substrate 100. That is, the size of the first sub-layer 311 is less than or equal to that of the second sub-layer 312, enabling the functional layer 400 to be more likely to break at the edge of the isolation structure 300 to form the first electrode 410 and the touch electrode 420.

In one embodiment, as shown in FIG. 11, the conductive portion 310 further includes a third sub-layer 313 on a side of the first sub-layer 311 facing the substrate 100, the orthographic projection of the first sub-layer 311 on the substrate 100 being within an orthographic projection of the third sub-layer 313 on the substrate 100, that is, the size of the first sub-layer 311 is less than or equal to the size of the third sub-layer 313, enabling the first electrode 410 to more likely to climb over the third sub-layer 313 to the first sub-layer 311 and to be electrically connected to the first sub-layer 311.

In one embodiment, the second sub-layer 312 and the third sub-layer 313 are made of a same material, to simplify the preparation process of the display panel.

In one embodiment, as shown in FIG. 14, the conductive portion 310 is a single-layer structural body, a cross-sectional area of the conductive portion 310 is gradually reduced in a direction from the conductive portion 310 to the substrate 100, and one side of the conductive portion 310 can form a recess, and the first electrode 410 and the touch electrode 420 can be disconnected at an edge of the conductive portion 310. For example, In one embodiment, the cross-sectional area of the isolation portion 301 is gradually reduced in a direction from the isolation portion 301 to the substrate 100, and the isolation portion 301 is formed by a negative photoresist.

As mentioned above, the material of the insulation portion 320 includes an organic material and/or an inorganic material. In one embodiment, as shown in FIG. 11, the light-emitting unit 230 includes a carrier layer, and the insulation portion 320 and the carrier layer may be made of a same material, and the insulation portion 320 and the carrier layer may be formed in the same process step. The carrier layer may include at least one of a hole injection layer, a hole transport layer, an electron blocking layer, a hole blocking layer, an electron transport layer or an electron injection layer.

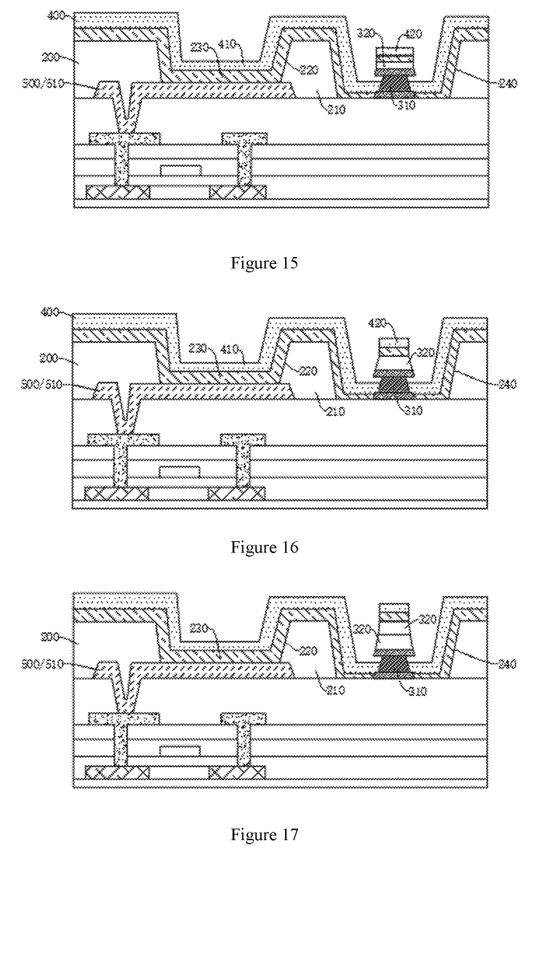

In one embodiment, as shown in FIG. 15, the material of the insulation portion 320 includes an inorganic material, making a thickness of the insulation portion 320 smaller. In one embodiment, as shown in FIG. 16, the material of the insulation portion 320 includes an organic material, making a thickness of the insulation portion 320 larger. In one embodiment, as shown in FIG. 17, the material of the insulation portion 320 includes an organic material and an inorganic material, that is, the insulation portion 320 includes two sub-layers to further increase the thickness of the insulation portion 320, enabling the first electrode 410 and the touch electrode 420 to be disconnected at the edge of the isolation structure 300.

An embodiment of a second aspect of the present application further provides a display apparatus, including a display panel according to any one of the above-described embodiments of the first aspect. Since the display apparatus according to the embodiment of the second aspect of the present application includes the display panel according to any one of the above-described embodiments of the first aspect, the display apparatus according to the embodiment of the second aspect of the present application has the beneficial effects of the display panel according to any one of the above-described embodiments of the first aspect, which will not be repeated herein.

The display apparatus in the embodiments of the present application includes, but is not limited to, devices having a display function, such as a mobile phone, a personal digital assistant (PDA), a tablet computer, an e-book reader, a television, an access control system, a smart fixed-line telephone, or a console.

Although the present application has been described with reference to some embodiments, various modifications can be made, and components can be replaced with equivalents, without departing from the scope of the present application. In particular, the embodiments can be combined in any manner, provided that there is no structural conflict. The present application is not limited to the embodiments disclosed herein but includes all the embodiments that fall within the scope of the claims.

1. A display panel, comprising:
a substrate;
an isolation structure arranged on the substrate, the isolation structure comprising isolation portions and isolation openings enclosed by the isolation portions, and a light-emitting unit being provided within a corresponding one of the isolation openings; and
a functional layer comprising first electrodes and touch electrodes, a corresponding one of the first electrodes being arranged within a corresponding one of the isolation openings and located on a side of the light-emitting unit away from the substrate, the touch electrodes being located on a side of the isolation portions away from the substrate, and the first electrodes being insulated and spaced apart from the touch electrodes.

2. The display panel according to claim 1, wherein each of the touch electrodes comprises a second touch portion and two or more first touch portions, the first touch portions extending in a first direction, and the two or more first touch portions being connected by the second touch portion.

3. The display panel according to claim 2, wherein the isolation portions comprise a first isolation portion and a second isolation portion, an orthographic projection of a corresponding one of the first touch portions on the substrate is within an orthographic projection of the first isolation portion on the substrate, and an orthographic projection of the second touch portion on the substrate is within an orthographic projection of the second isolation portion on the substrate.

4. The display panel according to claim 3, wherein at least two of the first touch portions have different extension lengths in the first direction, the touch electrodes further comprise a dummy electrode arranged on a side of a shorter first touch portion, and the dummy electrode is insulated from the first touch portion, the second touch portion, and the first electrodes.

5. The display panel according to claim 2, wherein each of the first electrodes comprises first electrode portions and a second electrode portion, a corresponding one of the first electrode portions being located between two adjacent ones of the first touch portions, a plurality of first electrode portions being spaced apart in the second direction, and the second electrode portion connecting two adjacent ones of the first electrode portions.

6. The display panel according to claim 5, wherein at least part of the second touch electrode portion and the second touch electrode portion are respectively arranged on two sides of the same first touch electrode portion in the first direction.

7. The display panel according to claim 2, wherein one or more pixel openings arranged in a second direction are provided between two adjacent ones of the first touch portions, the second direction intersecting the first direction.

8. The display panel according to claim 2, wherein each of the touch electrodes is a mutual-capacitive touch electrode, the touch electrode comprising a first touch electrode and a second touch electrode, and the first touch electrode and the second touch electrode each comprising first touch portions and a second touch portion.

9. The display panel according to claim 8, wherein at least among a first touch electrode and a second touch electrode that are adjacent, a first touch portion of the first touch electrode and a first touch portion of the second touch electrode are alternately distributed in a second direction; or
a plurality of second touch electrodes arranged side by side in a second direction are provided between two first touch electrodes adjacent in the first direction.

10. The display panel according to claim 9, wherein the display panel comprises a plurality pf touch areas, each of the touch areas being provided with a corresponding one of the touch electrodes, the plurality of touch areas being arranged in an array in a first direction and a second direction, and two adjacent ones of the touch areas having a same distance in the first direction and the second direction.

11. The display panel according to claim 1, wherein the touch electrodes are located in an active area of the display panel, the touch electrodes are self-capacitive touch electrodes, the functional layer further comprises touch leads connected to the touch electrodes, the touch leads are located on the side of the isolation portions away from the substrate, and a plurality of touch leads extend to at least two sides of the active area of the display panel.

12. The display panel according to claim 11, wherein the plurality of touch electrodes are arranged in an array in a first direction and a second direction, the active area of the display panel and the plurality of touch electrodes are symmetrically arranged about a first reference line in the second direction, and the touch leads connected to the touch electrodes located on two sides of the first reference line extend in a direction away from the first reference line.

13. The display panel according to claim 12, wherein the first reference line overlaps with a plurality of touch electrodes arranged in the second direction, and touch leads connected to the touch electrodes that overlap with the first reference line extend to two sides of the active area in the second direction; or
at least part of a corresponding one of the first electrodes is located between two adjacent touch leads that are at least partially overlap with each other.

14. The display panel according to claim 1, wherein the display panel further comprises a pixel define layer, the pixel define layer comprising a pixel defining portion and pixel openings enclosed by the pixel defining portion, a corresponding one of the isolation portions being arranged around a corresponding one of the pixel openings, and the light-emitting unit being located within a corresponding one of the pixel openings; and
the isolation structure is arranged on a side of the pixel defining portion away from the substrate; or
the pixel defining portion further encloses a clearance opening, and the isolation structure is located in the clearance opening and is spaced apart from an inner wall surface of the pixel defining portion facing the clearance opening; or
the substrate comprises a metal layer and an insulating dielectric layer located between the metal layer and the pixel define layer, wherein the pixel defining portion further encloses a clearance opening, the insulating dielectric layer is provided with a communication opening, the communication opening is in communication with the clearance opening, the isolation structure is arranged within the clearance opening and the communication opening, and the metal layer and at least part of the isolation portions are made of a same material; or
each of the isolation portions is formed by a recess in a surface of the pixel defining portion away from the substrate.

15. The display panel according to claim 1, wherein the isolation structure comprises a conductive portion and an insulation portion on a side of the conductive portion away from the substrate, the touch electrode being located on a side of the insulation portion away from the substrate, and a corresponding one of the first electrodes and the conductive portion being electrically connected to each other.

16. The display panel according to claim 15, wherein the insulation portion comprises an inorganic insulation layer and/or an organic insulation layer.

17. The display panel according to claim 15 wherein an orthographic projection of the conductive portion on the substrate is within an orthographic projection of the insulation portion on the substrate.

18. The display panel according to claim 15, wherein the conductive portion comprises a first sub-layer and a second sub-layer on a side of the first sub-layer away from the substrate, the first sub-layer and a corresponding one of the first electrodes being electrically connected to each other, an orthographic projection of the first sub-layer on the substrate being within an orthographic projection of the second sub-layer on the substrate, and the orthographic projection of the second sub-layer on the substrate being within an orthographic projection of the insulation portion on the substrate.

19. The display panel according to claim 18, the conductive portion further comprises a third sub-layer on a side of the first sub-layer facing the substrate, the orthographic projection of the first sub-layer on the substrate being within an orthographic projection of the third sub-layer on the substrate.

20. A display apparatus, comprising:
a display panel, comprising:
a substrate;
an isolation structure arranged on the substrate, the isolation structure comprising isolation portions and isolation openings enclosed by the isolation portions, and a light-emitting unit being provided within a corresponding one of the isolation openings; and
a functional layer comprising first electrodes and touch electrodes, a corresponding one of the first electrodes being arranged within a corresponding one of the isolation openings and located on a side of the light-emitting unit away from the substrate, the touch electrodes being located on a side of the isolation portions away from the substrate, and the first electrodes being insulated and spaced apart from the touch electrodes.
